(19) United States
(12) Patent Application Publication
(10) Pub. No.: US 2015/0253349 A1
(43) Pub. Date: Sep. 10, 2015

(54) ACCELERATION SENSOR

(71) Applicant: Murata Manufacturing Co., Ltd., Nagaokakyo-shi (JP)

(72) Inventor: Daichi EIYAMA, Nagaokakyo-shi (JP)

(21) Appl. No.: 14/715,639

(22) Filed: May 19, 2015

Related U.S. Application Data
(63) Continuation of application No. PCT/JP2013/082546, filed on Dec. 4, 2013.

(30) Foreign Application Priority Data
Dec. 6, 2012 (JP) 2012-267346

(51) Int. Cl. G01P 15/12; B81B 7/02

(52) U.S. Cl. CPC G01P 15/123; B81B 7/02

(57) ABSTRACT

An acceleration sensor element includes a weight portion, a base portion that has a frame shape surrounding the weight portion, a beam portion that supports the weight portion on the base portion, and a strain detector portion on the beam portion. The base portion includes four frame sides. The acceleration sensor is mounted such that one of the frame sides of the acceleration sensor element faces a mounting surface of a component-receiving board. In other words, the beam portion of the acceleration sensor element is located at the frame side opposite to the mounting surface.

### BACKGROUND OF THE INVENTION

1. Field of the Invention

The present invention relates to acceleration sensors using MEMS technology.

2. Description of the Related Art

Typically, acceleration sensors using MEMS technology measure acceleration based on the change in resistance value of a piezo-resistance portion at a beam in response to stress produced in the beam due to displacement of a weight portion. Such a typical MEMS acceleration sensor is described, for example, in Japanese Unexamined Patent Application Publication No. 2004-264053.

In the acceleration sensor described in Japanese Unexamined Patent Application Publication No. 2004-264053, a hollow space is formed inside a silicon base body. Inside the hollow space, a beam portion formed into a bridge structure supports a weight portion that is rectangular in shape and allowed to move in three-dimensional directions. A piezo-resistance portion is formed at the beam portion.

In conventional acceleration sensors using MEMS technology, the weight portion and its vicinity are structured so as to maximize stress produced at the beam portion for detecting the displacement of the weight portion. Thus, of constituting elements of the acceleration sensor, the weight portion and its vicinity are most easily displaced. Further, structurally, the acceleration sensor includes a base portion that has a frame-like shape surrounding the weight portion, and the beam portion is formed so as to support the weight portion on the base portion. Typically, as described in the Japanese Unexamined Patent Application Publication No. 2004-264053, the base portion is bonded to a supporting surface in such a way that one of principle surfaces (bottom surface) of the frame-like shape portion is bonded to the supporting surface.

However, in a structure configured such that the base portion is bonded to the supporting surface on the one of the principle surfaces (bottom surface) of the frame-like shape portion, the acceleration sensor is in a state of being mounted on a board and receives deformation or deflection of the board. When the deformation or deflection occurs at the supporting surface, stress is exerted on the beam portion via the base portion. As a result, the deformation or deflection of the supporting surface causes a displacement in the beam, and noise content (offset bias) that should not be detected in a normal situation is added.

### SUMMARY OF THE INVENTION

Preferred embodiments of the present invention provide an acceleration sensor whose noise content is significantly reduced by making the acceleration sensor less susceptible to deformation or deflection of a component-receiving board.

An acceleration sensor according to a preferred embodiment of the present invention includes a weight portion; a base portion including a plurality of frame sides that surround the weight portion; a beam portion supporting the weight portion on the base portion; and a strain detector portion on the beam portion, wherein, of the plurality of frame sides of the base portion, the beam portion is located at the frame side that is different from the frame side connected to a mounting surface.

Preferably, of the plurality of frame sides of the base portion, the beam portion is located at the frame side separated from the mounting surface, for example, the opposite side.

Accordingly, various preferred embodiments of the present invention provide acceleration sensors that alleviate the effects of deformation or deflection of a component-receiving board and significantly reduce noise produced thereby.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a three-view drawing of an acceleration sensor element 100 according to a first preferred embodiment of the present invention.

FIG. 2 is a view depicting a relationship between directions of the acceleration sensor element 100 and a component-receiving board.

FIG. 3 is a perspective view of a mount state where an acceleration sensor 200 according to a preferred embodiment of the present invention is mounted on a board 20.

FIG. 4 is a view depicting a relationship between directions of an acceleration sensor element 100 according to a second preferred embodiment and a component-receiving board.

FIG. 5 is a view depicting a relationship between directions of an acceleration sensor element that serves as a comparative example and a component-receiving board.

### DETAILED DESCRIPTION OF THE PREFERRED EMBODIMENTS

### First Preferred Embodiment

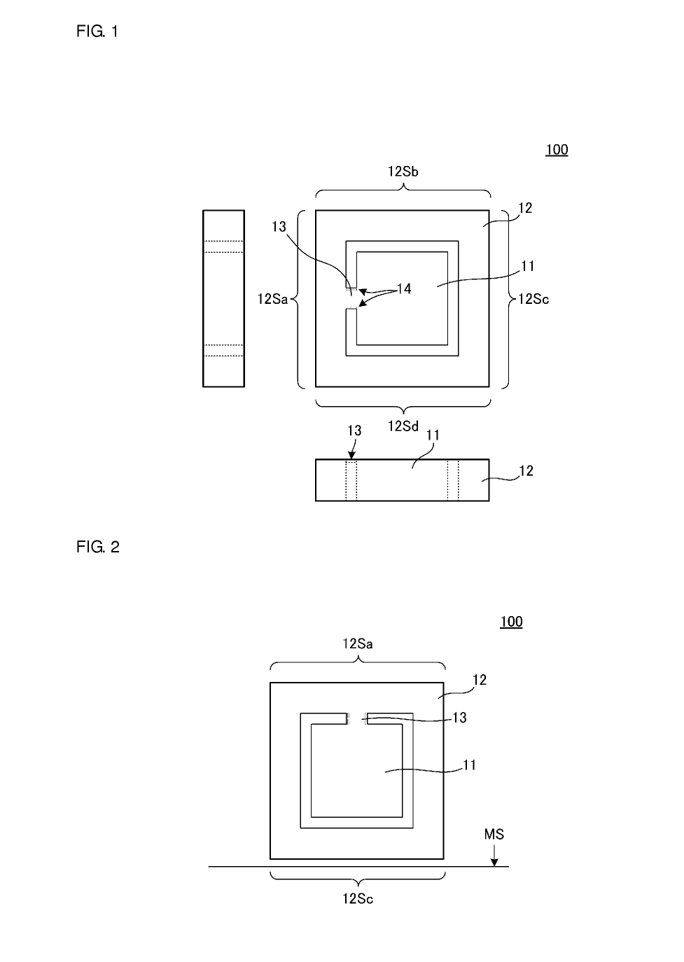

FIG. 1 is a three-view drawing of an acceleration sensor element 100 according to the first preferred embodiment of the present invention. This acceleration sensor element 100 is packaged in the following way, which will be described below. The acceleration sensor element 100 includes a weight portion 11, a base portion 12 that has a frame shape surrounding the weight portion 11, a beam portion 13 that supports the weight portion 11 on the base portion 12, and a strain detector portion 14 provided on the beam portion 13.

The weight portion 11, the base portion 12, and the beam portion 13 are formed preferably by processing a Si substrate using MEMS technology, for example. The Si substrate preferably has a square or substantially square plate shape, and the thickness dimensions of the weight portion 11 and the base portion 12 are equal or substantially equal to each other within manufacturing tolerances.

The base portion 12 includes four frame sides 12Sa, 12Sb, 12Sc, and 12Sd. Piezoresistive elements are provided on the beam portion 13 at four locations, and a resistance bridge circuit is defined by these four piezoresistive elements.

FIG. 2 is a view depicting a relationship between directions of the acceleration sensor element 100 and a component-receiving board. In this example, the acceleration sensor is preferably mounted in such a way that the frame side 12Sc of the acceleration sensor element 100 faces a mounting surface MS of the component-receiving board. In other words, of the four frame sides of the base portion 12, the beam portion 13 of the acceleration sensor element 100 is provided at the frame side that is different from the frame side connected to the mounting surface MS. In the present example, the beam portion 13 is provided at the frame side 12Sa located at the side (upper surface side) opposite to and separated from the mounting surface MS.

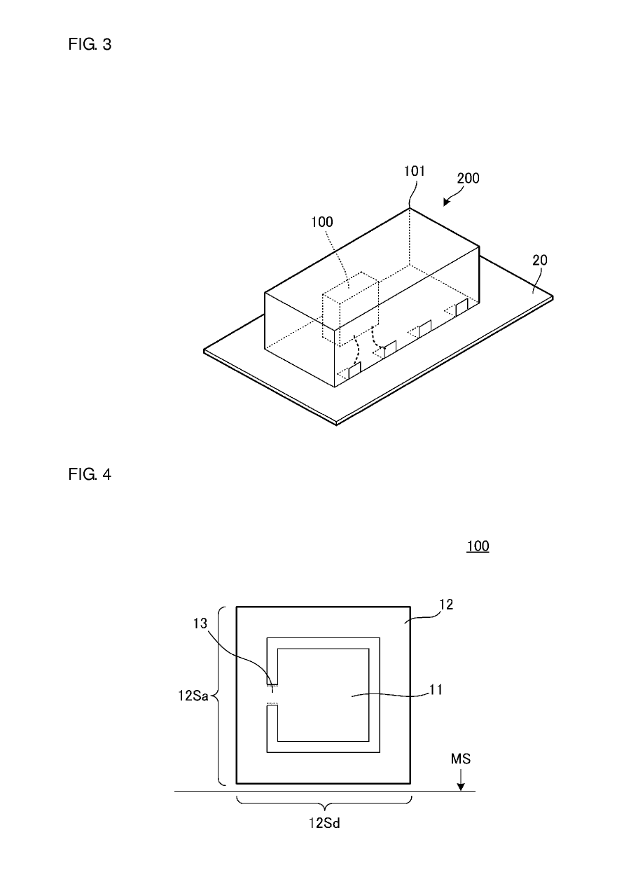

FIG. 3 is a perspective view of a mount state where an acceleration sensor 200 according to a preferred embodiment of the present invention is mounted on a board 20. The acceleration sensor 200 includes the acceleration sensor element 100 therein, and the acceleration sensor element 100 is surrounded with molding resin 101 for packaging. The acceleration sensor element 100 is vertically positioned with respect to the mounting surface (bottom surface) of the acceleration sensor 200. Further, as depicted in FIG. 2, the frame side at which the beam portion 13 of the acceleration sensor element 100 is located is arranged so as to be positioned at the side (upper surface side) opposite to the mounting surface.

Accordingly, the configuration described above provides the acceleration sensor that alleviates effects of deformation or deflection of a component-receiving board and achieves much lower noise content.

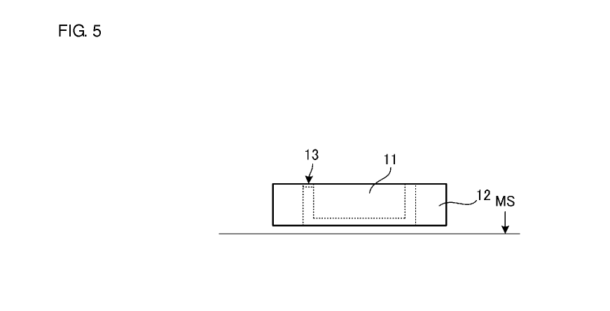

Here, a relationship between directions of an acceleration sensor element that serves as a comparative example and a component-receiving board is depicted in FIG. 5. Since this is the comparison example, the basic configuration of the acceleration sensor element is similar to that described in the first preferred embodiment of the present invention. In this example, a base portion 12 is arranged such that one of principle surfaces (bottom surface) of the base portion 12 faces a mounting surface MS of the component-receiving board.

In the arrangement illustrated in FIG. 5, stress is exerted on a beam portion 13 via the base portion 12 when deformation or deflection occurs at the component-receiving board in the state where an acceleration sensor is mounted on the component-receiving board. As a result, the deformation or deflection of the board causes a displacement in the beam, and noise content (offset bias) that should not be detected in a normal situation is superimposed.

On the other hand, according to preferred embodiments of the present invention, when deformation or deflection occurs at the board, stress is exerted on the frame sides of the base portion 12, but the stress is less likely to reach the beam portion. Particularly, in the case where the beam portion 13 is provided at the frame side at the side (upper surface side) opposite to the mounting surface, effects or impacts to the beam portion become negligible. Accordingly, the acceleration sensor that produces a detection signal with lower noise content is obtained.

### Second Preferred Embodiment

FIG. 4 is a view depicting a relationship between directions of an acceleration sensor element 100 according to the second preferred embodiment of the present invention and a component-receiving board. In this example, the acceleration sensor is preferably mounted in such a way that a frame side 12Sd of the acceleration sensor element 100 faces a mounting surface MS of the component-receiving board. In other words, of four frame sides of a base portion 12, a beam portion 13 of the acceleration sensor element 100 is located at a frame side 12Sa that is vertical to the mounting surface.

Even in the arrangement illustrated in FIG. 4, the beam portion 13 is at a location spaced from the mounting surface MS. Thus, stress due to the deformation or deflection occurred at the board is much less likely to reach the beam portion.

In the examples illustrated in FIG. 2 and FIG. 4, the direction along which the beam portion 13 extends preferably is in vertical and horizontal relationships with respect to the mounting surface MS, respectively. Alternatively, it may be inclined. For example, the inclination angle may be about 45 degrees or about 135 degrees.

The preferred embodiments described above provide the examples in which the weight portion 11, the base portion 12, and the beam portion 13 are formed preferably by processing the substrate having a square or substantially square plate shape. However, in the present invention, the shape of the substrate is not limited to the square or substantially square plate shape, and may alternatively be, for example, a triangular or substantially triangular plate shape or a circular or substantially circular plate shape.

Further, the preferred embodiments described above provide the examples in which the piezoresistive elements are preferably provided at the strain detector portion and connected into a bridge. However, the present invention is not limited thereto and may alternatively be provided with a functional portion that converts a mechanical strain into an electronic signal.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. An acceleration sensor comprising:
a weight portion;
a base portion including a plurality of frame sides that surround the weight portion;
a beam portion supporting the weight portion on the base portion; and
a strain detector portion provided on the beam portion; wherein
the beam portion is located at one of the plurality of frame sides that is different from another of the plurality of frame sides connected to a mounting surface of a component-receiving board.

3. The acceleration sensor according to claim 2, wherein the one of the plurality of frame sides at which the beam portion is located is spaced from the mounting surface.

4. The acceleration sensor according to claim 2, wherein the weight portion, the base portion, and the beam portion are defined by an Si substrate.

5. The acceleration sensor according to claim 4, wherein the Si substrate is configured to use MEMS technology.

6. The acceleration sensor according to claim 4, wherein the Si substrate has a square or substantially square shape.

7. The acceleration sensor according to claim 2, wherein thickness dimensions of the weight portion and the base portion are equal or substantially equal.

8. The acceleration sensor according to claim 2, wherein piezoresistive elements are provided on the beam portion at four locations.

9. The acceleration sensor according to claim 8, wherein the piezoresistive elements define a bridge circuit.

10. The acceleration sensor according to claim 2, further comprising resin defining a package for the acceleration sensor.

11. The acceleration sensor according to claim 2, wherein the one of the plurality of frame sides at which the beam portion is located is vertical to the mounting surface of the component-receiving board.

12. The acceleration sensor according to claim 4, wherein the Si substrate has a triangular or substantially triangular plate shape or a circular or substantially circular plate shape.

13. The acceleration sensor according to claim 2, further comprising a functional portion configured to convert mechanical strain into an electronic signal.
